(19) United States
(12) Patent Application Publication
(10) Pub. No.: US 2014/0248444 A1
(43) Pub. Date: Sep. 4, 2014

(54) Plasma Treatment Of Substrates

(71) Applicants: Centre National de la Recherche Scientifique, Paris (FR); Dow Corning Corporation, Midland, MI (US)

(72) Inventors: Francoise Massines, Sorede (FR); Thomas Gaudy, Montescot (FR); Pierre Descamps, Rixensart (BE); Patrick Leempoel, Bruxelles (BE); Vincent Kaiser, Seneffe (BE); Syed Salman Asad, Ixelles (BE)

(21) Appl. No.: 14/348,719

(22) PCT Filed: Nov. 2, 2012
(86) PCT No.: PCT/EP2012/004579

§ 371 Date: Mar. 31, 2014

(30) Foreign Application Priority Data
Nov. 9, 2011 (EP) EP 11306460.4

(51) Int. Cl. C23C 16/50

(52) U.S. Cl. CPC C23C 16/50
USPC 427/569; 118/723 R

(57) ABSTRACT

An apparatus for plasma treating a substrate comprises a high voltage source of frequency 3 kHz to 30 kHz connected to at least one needle electrode (11) positioned within a channel (16) inside a dielectric housing (14) having an inlet for process gas and an outlet. The channel (16) has an entry (16a) which forms the said inlet for process gas and an exit (16e) into the dielectric housing arranged so that process gas flows from the inlet through the channel (16) past the electrode (11) to the outlet of the dielectric housing. The apparatus includes means for introducing an atomised surface treatment agent in the dielectric housing, and support means (27, 28) for the substrate (25) adjacent to the outlet of the dielectric housing. The needle electrode (11) extends from the channel entry (16a) to a tip (11t) close to the exit (16e) of the channel and projects outwardly from the channel (16) so that the tip (11t) of the needle electrode is positioned in the dielectric housing close to the exit (16e) of the channel at a distance outside the channel of at least 0.5 mm up to 5 times the hydraulic diameter of the channel. The channel (16) has a ratio of length to hydraulic diameter greater than 10:1.

The present invention relates to treating a substrate using a plasma system. In particular it relates to the deposition of a thin film on a substrate from a non-local equilibrium atmospheric pressure plasma incorporating an atomised surface treatment agent.

When matter is supplied with energy, it typically transforms from a solid to a liquid and, then, to a gaseous state. Continuing to supply energy causes the system to undergo yet a further change of state in which neutral atoms or molecules of the gas are broken up by energetic collisions to produce negatively charged electrons, positive or negatively charged ions and other excited species. This mix of charged and other excited particles exhibiting collective behaviour is called “plasma”, the fourth state of matter. Due to their free electrical charge (free to move in response to application of a field), plasmas are highly influenced by external electromagnetic fields, which make them readily controllable. Furthermore, their high energy content/species allows them to achieve processes which are impossible or difficult through the other states of matter, such as by liquid or gas processing.

The term “plasma” covers a wide range of systems whose density and temperature vary by many orders of magnitude. Some plasmas are very hot, for example a flame based plasma as formed by a plasma torch, and all their microscopic species (ions, electrons, etc.) are in approximate thermal equilibrium, the energy input into the system being widely distributed through atomic/molecular level collisions. Other plasmas, however, have their constituent species at widely different temperatures and are said to be in “non-local thermal equilibrium”. In these non-local thermal equilibrium plasmas the free electrons are very hot with temperatures of many thousands of Kelvin (K) whilst the neutral and ionic species remain cool (temperatures orders of magnitude below those of electrons). Because the free electrons have almost negligible mass, the total system heat content is low and the plasma may operate close to room temperature thus allowing the processing of temperature sensitive materials, such as plastics or polymers, without imposing a damaging thermal burden onto the sample. However, the hot electrons create, through high energy collisions, a rich source of radicals and excited species with a high chemical potential energy capable of profound chemical and physical reactivity. It is this combination of low temperature operation plus high reactivity which makes non-thermal plasma technologically important and a very powerful tool for manufacturing and material processing, capable of achieving processes which, if achievable at all without plasma, would require very high temperatures or noxious and aggressive chemicals.

For industrial applications of plasma technology, a convenient method is to couple electromagnetic power into a volume of process gas. A process gas may be a single gas or a mixture of gases and vapours which is excitable to a plasma state by the application of the electromagnetic power. Workpieces/samples are treated by the plasma generated by being immersed or passed through the plasma itself or charged and/or excited species derived therefrom because the process gas becomes ionised and excited, generating species including chemical radicals, and ions as well as UV-radiation, which can react or interact with the surface of the workpieces/samples. By correct selection of process gas composition, driving power frequency, power coupling mode, pressure and other control parameters, the plasma process can be tailored to the specific application required by a manufacturer.

Because of the huge chemical and thermal range of plasmas, they are suitable for many technological applications. Non-thermal equilibrium plasmas are particularly effective for surface activation, surface cleaning, material etching and coating of surfaces.

Since the 1960s the microelectronics industry has developed the low pressure Glow Discharge plasma into an ultra-high technology and high capital cost engineering tool for semiconductor, metal and dielectric processing. The same low pressure Glow Discharge type plasma has increasingly penetrated other industrial sectors since the 1980s offering polymer surface activation for increased adhesion/bond strength, high quality degreasing/cleaning and the deposition of high performance coatings. Glow discharges can be achieved at both vacuum and atmospheric pressures. In the case of atmospheric pressure glow discharge, electromagnetic energy generated by a power supply is coupled in to gases such as helium, argon, nitrogen or air to generate a homogeneous glow or a filamentary discharge at atmospheric pressure, depending on the different ionisation mechanisms occurring in the discharge.

A variety of “plasma jet” systems have been developed, as means of atmospheric pressure plasma treatment. Plasma jet systems generally consist of a gas stream which is directed between two electrodes. As power is applied between the electrodes, a plasma is formed and this produces a mixture of ions, radicals and active species which can be used to treat various substrates. The plasma produced by a plasma jet system is directed from the space between the electrodes (the plasma zone) as a flame-like phenomenon and can be used to treat remote objects.

U.S. Pat. Nos. 5,198,724 and 5,369,336 describe “cold” or non-thermal equilibrium atmospheric pressure plasma jet (hereafter referred to as APPJ), which consisted of an RF powered metal needle acting as a cathode, surrounded by an outer cylindrical anode. U.S. Pat. No. 6,429,400 describes a system for generating a blown atmospheric pressure glow discharge (APGD). This comprises a central electrode separated from an outer electrode by an electrical insulator tube. The inventor claims that the design does not generate the high temperatures associated with the prior art. Kang et al (Surf Coat. Technol., 2002, 171, 141-148) have also described a 13.56 MHz RF plasma source that operates by feeding helium or argon gas through two coaxial electrodes. In order to prevent an arc discharge, a dielectric material is loaded outside the central electrode. WO94/14303 describes a device in which an electrode cylinder has a pointed portion at the exit to enhance plasma jet formation.

U.S. Pat. No. 5,837,958 describes an APPJ based on coaxial metal electrodes where a powered central electrode and a dielectric coated ground electrode are utilised. A portion of the ground electrode is left exposed to form a bare ring electrode near the gas exit. The gas flow (air or argon) enters through the top and is directed to form a vortex, which keeps the arc confined and focused to form a plasma jet. To cover a wide area, a number of jets can be combined to increase the coverage.

U.S. Pat. No. 6,465,964 describes an alternative system for generating an APPJ, in which a pair of electrodes is placed around a cylindrical tube. Process gas enters through the top of the tube and exits through the bottom. When an AC electric field is supplied between the two electrodes, plasma is generated by passing a process gas there between within the tube and this gives rise to an APPJ at the exit. The position of the electrodes ensures that the electric field forms in the axial direction. In order to extend this technology to the coverage of wide area substrates, the design can be modified, such that the central tube and electrodes are redesigned to have a rectangular tubular shape. This gives rise to a wide area plasma, which can be used to treat large substrates such as reel-to-reel plastic film.

U.S. Pat. No. 5,798,146 describes formation of plasma using a single sharp needle electrode placed inside a tube and applying a high voltage to the electrode produces a leakage of electrons, which further react with the gas surrounding the electrode, to produce a flow of ions and radicals. As there is no second electrode, this does not result in the formation of an arc. Instead, a low temperature plasma is formed which is carried out of the discharge space by a flow of gas. Various nozzle heads have been developed to focus or spread the plasma. The system may be used to activate, clean or etch various substrates. Stoffels et al (Plasma Sources Sci. Technol., 2002, 11, 383-388) have developed a similar system for biomedical uses.

WO 02/028548 describes a method for forming a coating on a substrate by introducing an atomized liquid and/or solid coating material into an atmospheric pressure plasma discharge or an ionized gas stream resulting therefrom. WO 02/098962 describes coating a low surface energy substrate by exposing the substrate to a silicon compound in liquid or gaseous form and subsequently post-treating by oxidation or reduction using a plasma or corona treatment, in particular a pulsed atmospheric pressure glow discharge or dielectric barrier discharge.

WO 03/097245 and WO 03/101621 describe applying an atomised coating material onto a substrate to form a coating. The atomised coating material, upon leaving an atomizer such as an ultrasonic nozzle or a nebuliser, passes through an excited medium (plasma) to the substrate. The substrate is positioned remotely from the excited medium. The plasma is generated in a pulsed manner.

WO2006/048649 describes generating a non-equilibrium atmospheric pressure plasma incorporating an atomised surface treatment agent by applying a radio frequency high voltage to at least one electrode positioned within a dielectric housing having an inlet and an outlet while causing a process gas to flow from the inlet past the electrode to the outlet. The electrode is combined with an atomiser for the surface treatment agent within the housing. The non-equilibrium atmospheric pressure plasma extends from the electrode at least to the outlet of the housing so that a substrate placed adjacent to the outlet is in contact with the plasma, and usually extends beyond the outlet. WO2006/048650 teaches that the flame-like non-equilibrium plasma discharge, sometimes called a plasma jet, could be stabilized over considerable distances by confining it to a long length of tubing. This prevents air mixing and minimises quenching of the flame-like non-equilibrium plasma discharge. The flame-like non-equilibrium plasma discharge extends at least to the outlet, and usually beyond the outlet, of the tubing.

WO03/085693 describes an atmospheric plasma generation assembly having a reactive agent introducing means, a process gas introducing means and one or more multiple parallel electrode arrangements adapted for generating a plasma. The assembly is adapted so that the only means of exit for a process gas and atomised liquid or solid reactive agent introduced into said assembly is through the plasma region between the electrodes. The assembly is adapted to move relative to a substrate substantially adjacent to the electrodes outermost tips. Turbulence may be generated in the plasma generation assembly to ensure an even distribution of the atomised spray.

The paper “Generation of long laminar plasma jets at atmospheric pressure and effects of flow turbulence” by Wenxia Pan et al in ‘Plasma Chemistry and Plasma Processing’, Vol. 21, No. 1, 2001 shows that laminar flow plasma with very low initial turbulent kinetic energy will produce a long jet with low axial temperature gradient and suggests that this kind of long laminar plasma jet could greatly improve the controllability for materials processing, compared with a short turbulent arc jet.

The paper “Analysis of mass transport in an atmospheric pressure remote plasma enhanced chemical vapor deposition process” by R. P. Cardoso et al in ‘Journal of Applied Physics’ Vol. 107, 024909 (2010) shows that in remote microwave plasma enhanced chemical vapor deposition processes operated at atmospheric pressure, high deposition rates are associated with the localization of precursors on the treated surface, and that mass transport can be advantageously ensured by convection for the heavier precursor, the lighter being driven by turbulent diffusion toward the surface.

WO2009/034012 describes a process for coating a surface, in which an atomized surface treatment agent is incorporated in a non-equilibrium atmospheric pressure plasma generated in a noble process gas or an excited and/or ionised gas stream resulting therefrom, and the surface to be treated is positioned to receive atomized surface treatment agent which has been incorporated therein, is characterized in that the particle content of the coating formed on the surface is reduced by incorporating a minor proportion of nitrogen in the process gas. However the addition of nitrogen is detrimental to the energy available for precursor dissociation.

The use of atmospheric plasma technologies for thin film deposition offers a lot of benefits versus alternative low pressure plasma deposition in terms of capital cost (no need for vacuum chamber or vacuum pumps) or maintenance. This is particularly true for a jet-like technology, such as that described in WO2006/048649 and WO2006/048650, that allows precise deposition on the substrate. One of the major issues related to atmospheric plasma deposition technologies and more particularly to atmospheric plasma jets is the large consumption of process gas during the deposition process. When helium is used for obtaining a stable, filament-free discharge, the gas consumption may lead to unacceptably large process costs. It is thus essential to find ways to reduce the process gas consumption during thin film deposition.

An apparatus according to the invention for plasma treating a substrate comprises a high voltage source of frequency 3 kHz to 300 kHz connected to at least one needle electrode positioned within a channel inside a dielectric housing having an inlet for process gas and an outlet, the channel having an entry which forms the said inlet for process gas and an exit into the dielectric housing arranged so that process gas flows from the inlet through the channel past the electrode to the outlet of the dielectric housing, means for introducing an atomised surface treatment agent in the dielectric housing, and support means for the substrate adjacent to the outlet of the dielectric housing. It is characterised in that the needle electrode extends from the channel entry to a tip close to the exit of the channel and projects outwardly from the channel so that the tip of the needle electrode is positioned in the dielectric housing close to the exit of the channel at a distance outside the channel of at least 0.5 mm up to 5 times the hydraulic diameter of the channel, and the channel has a ratio of length to hydraulic diameter greater than 10:1. By a high voltage we mean a root mean square potential of at least 1 kV. The high voltage source may operate at any frequency between. 0 and 15 MHz.

The length of the electrode and the length of the channel can be measured with a vernier caliper. The difference is calculated to obtain the distance by which the tip of the needle electrode is outside the channel, that is the distance between the needle tip and the exit of the channel. The channel, which is usually but not necessarily of circular cross-section, generally surrounds the electrode, so that the process gas passes through a channel of annulus cross-section surrounding the electrode.

In a process according to the invention for plasma treating a substrate by applying a high voltage to at least one needle electrode positioned within a channel inside a dielectric housing having an inlet and an outlet, the channel having an entry which forms the said inlet for process gas and an exit into the dielectric housing, while causing a process gas to flow from the inlet through the channel past the electrode to the outlet of the dielectric housing, thereby generating a non-local thermal equilibrium atmospheric pressure plasma, incorporating an atomised or gaseous surface treatment agent in the non-local thermal equilibrium atmospheric pressure plasma, and positioning the substrate adjacent to the outlet of the dielectric housing so that the surface of the substrate is in contact with the plasma and is moved relative to the outlet of the dielectric housing, the needle electrode extends from the channel entry to a tip close to the exit of the channel and projects outwardly from the channel so that the tip of the needle electrode is positioned in the dielectric housing close to the exit of the channel at a distance outside the channel of at least 0.5 mm up to 5 times the hydraulic diameter of the channel, and the channel has a ratio of length to hydraulic diameter greater than 10:1.

The hydraulic diameter, D_{H}, is a commonly used term when handling flow in noncircular tubes and channels. It is defined by the equation D_{H}=4A/P, where A is the cross-sectional area of the tube or channel and P is the wetted perimeter of the cross-section. The wetted perimeter is the perimeter which is in contact with the fluid (the process gas). In the case of a circular tube, the wetted perimeter is the internal perimeter of the tube. In case of an annulus, there are two perimeters in contact with the fluid: the perimeter of the inside and outside part of the annulus. In this case the wetted perimeter=π(Do+Di) with Do and Di meaning for outside and inside diameter. For a channel with an electrode positioned at its center, the outside diameter of the annulus Do is the internal diameter of the channel, while the inside diameter of the annulus Di is the diameter of the electrode. These diameters can be measured with a vernier caliper. For a round tube of diameter D, A=πD²/4 and P=πD, so that D_{H}=D. For an annulus between an outer pipe of internal diameter Do and a solid core of diameter Di, A=π(Do²−Di²)/4 and P=π(Do+Di), so that D_{H}=Do−Di. Thus in the case of a channel with the electrode positioned at its center, the hydraulic diameter of the pipe is equal to the internal diameter of the channel minus the diameter of the electrode.

We have found according to the invention that the directionality of the gas flow leaving the channel is important. As the length of the channel is increased to stabilize the flow inside the channel, a directional flow of gas is directed toward the needle tip, forcing the process gas to pass through the high electric field region. The flow stabilization resulting from channel length is observed both for laminar flow and for turbulent flow. In the case of laminar flow, the jet deviates from laminar behaviour if the length of the channel is less than 10 times its hydraulic diameter, and spreads much more rapidly. Jet spreading is characterized by a sudden increase in jet cross-section and a sudden decrease in velocity in the direction of the jet axis. Deviation from laminar behaviour is shown for a channel length less than 8 times the hydraulic diameter, while a fully stabilised flow is observed for a channel length equal to 20 times the hydraulic diameter. For turbulent flow, the jet shows laminar behaviour over a distance of about 5 times the hydraulic diameter of the channel if the length of the channel is more than 10 times its hydraulic diameter, and then switches to turbulent behaviour. If the length of the channel is less than 10 times its hydraulic diameter, the distance between the channel exit and the zone of transition to turbulent behaviour decreases, possibly giving a jet that spreads right at the tube exit. The effect of channel length on flow stabilization is not a threshold effect, but is a continuous transition with the increase in channel length. At a channel length 10 times the hydraulic diameter the benefit of flow stabilization (directionality of the flow) starts to be significant for both turbulent and laminar flow. Furthermore, we have found that the position of the needle tip with respect to the channel exit has an impact on the intensity of the discharge. It was found that having the needle tip located inside the channel leads to a less intense discharge. On the contrary, with the needle tip positioned slightly outside the channel, we observe a brighter discharge and a larger deposition rate. The needle tip is positioned at a distance from the channel exit at which the flow stays directional. For turbulent flow, this is a distance of up to about 5 times the hydraulic diameter of the channel.

Plasma can in general be any type of non-equilibrium atmospheric pressure plasma or corona discharge. Examples of non-equilibrium atmospheric pressure plasma discharge include dielectric barrier discharge and diffuse dielectric barrier discharge such as glow discharge plasma. A diffuse dielectric barrier discharge e.g. a glow discharge plasma is preferred. Preferred processes are “low temperature” plasmas wherein the term “low temperature” is intended to mean below 200° C., and preferably below 100° C.

The invention will be described with reference to the accompanying drawings, of which

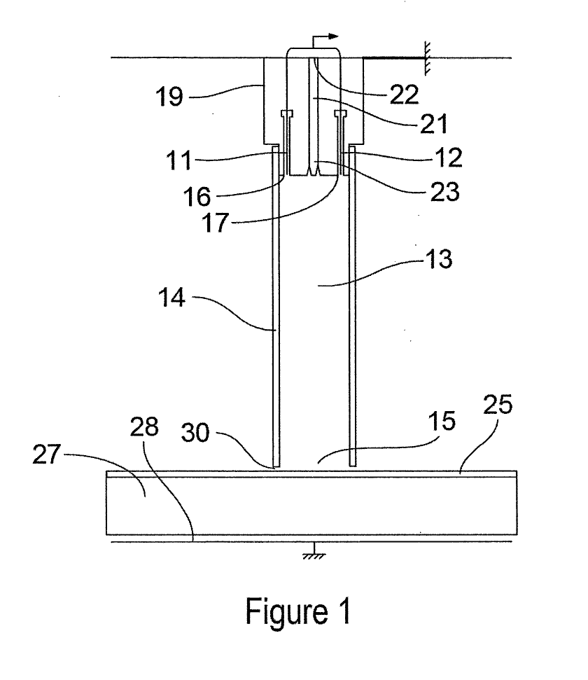

FIG. 1 is a diagrammatic cross section of an apparatus according to the invention for generating a non-equilibrium atmospheric pressure plasma incorporating an atomised surface treatment agent; and

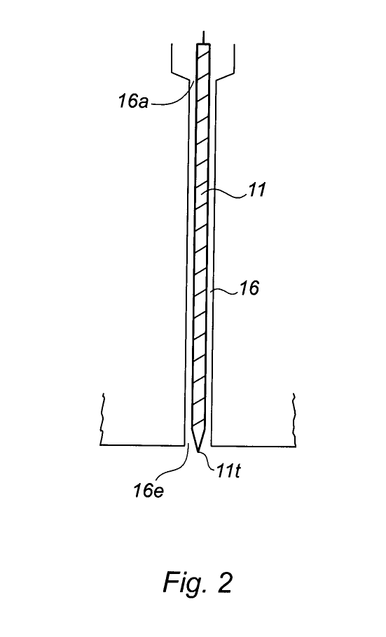

FIG. 2 is an enlarged cross-section of one electrode and channel of the apparatus of FIG. 1.

The apparatus of FIG. 1 comprises two electrodes (11, 12) positioned within a plasma tube (13) defined by a dielectric housing (14) and having an outlet (15). The electrodes (11, 12) are needle electrodes both having the same polarity and are connected to a suitable power supply. Although the power supply to the electrode or electrodes may operate at any frequency between 0 to 14 MHz (0 MHz means direct current discharge), it is preferably a low to radio frequency power supply as known for plasma generation, that is in the range 3 kHz to 300 kHz. The root mean square potential of the power supplied is generally in the range 1 kV to 100 kV, preferably between 4 kV and 30 kV. The electrodes (11, 12) are each positioned within a narrow channel (16 and 17 respectively), for example of radius 0.1 to 5 mm, preferably 0.2 to 2 mm, greater than the radius of the electrode, communicating with plasma tube (13). The tip of each needle electrode (11 and 12) is positioned close to the exit of the associated channel (16 and 17 respectively).

In the apparatus seen more clearly in FIG. 2, the electrode (11) is 1 mm in diameter and is positioned centrally within a channel (16) of length from its entry (16a) to its exit (16e) 30mm and internal diameter 2 mm. The hydraulic diameter of the channel (16) is 1 mm. The channel has a ratio of length to hydraulic diameter of 30:1. The ratio of length to hydraulic diameter of each channel surrounding an electrode is at least 10:1, preferably at least 20:1, most preferably at least 30:1. There is no maximum channel length since the longer the channel, more stable will be the gas flow. For a too small channel length, the flow is not stabilized and becomes turbulent immediately at the channel exit, dispersing the gas within the plasma tube (13) and not forcing it to pass through the high electric field region. The excited species may be lost to the walls of the dielectric housing (14).

As seen more clearly in FIG. 2, the tip (11t) of the electrode (11) is positioned 0.5 mm outside the exit (16e) of the channel (16). In general the tip (11t) of the needle electrode is positioned between 0.5 mm outside the channel (16), that is 0.5 mm downstream of the channel exit (16e), and a distance outside the channel of 5 times the hydraulic diameter of the channel, which is equal in the apparatus of FIGS. 1 and 2 to 5 mm downstream of the channel exit (16e). We have found that having the needle tip (11t) located inside the channel (16) leads to a less intense discharge. On the contrary, with the needle tip (11t) positioned slightly outside the channel exit (16e), we observe a brighter discharge and a larger deposition rate of surface treatment agent on the substrate.

The process gas is fed to a chamber (19) whose outlets are the channels (16, 17) surrounding the electrodes. The chamber (19) is made of a heat resistant, electrically insulating material which is fixed in an opening in the base of a metal box. The metal box is grounded but grounding of this box is optional. The chamber (19) can alternatively be made of an electrically conductive material, provided that all the electrical connections are insulated from the ground, and any part in potential contact with the plasma is covered by a dielectric. The entries to channels (16, 17) thus form the inlet to dielectric housing (14) for process gas.

An atomiser (21) having an inlet (22) for surface treatment agent is situated adjacent to the electrode channels (16, 17) and has atomising means (not shown) and an outlet (23) feeding atomised surface treatment agent to the plasma tube (13). The chamber (19) holds the atomiser (21) and needle electrodes (11, 12) in place. The dielectric housing (14) can be made of any dielectric material. Experiments described below were carried out using quartz dielectric housing (14) but other dielectrics, for example glass or ceramic or a plastic material such as polyamide, polypropylene or polytetrafluoroethylene, for example that sold under the trade mark ‘Teflon’, can be used. The dielectric housing (14) can be formed of a composite material, for example a fiber reinforced plastic designed for high temperature resistance.

The substrate (25) to be treated is positioned at the plasma tube outlet (15). The substrate (25) is laid on a support (27, 28). The substrate (25) is arranged to be movable relative to the plasma tube outlet (15). The support (27, 28) can for example be a dielectric layer (27) covering a metal supporting plate (28). The dielectric layer (27) is optional. The metal plate (28) as shown is grounded but grounding of this plate is optional. If the metal plate (28) is not grounded, this may contribute to the reduction of arcing onto a conductive substrate, for example a silicon wafer. The gap (30) between the outlet end of the dielectric housing (14) and the substrate (25) is the only outlet for the process gas fed to the plasma tube (13). The surface area of the gap (30) between the outlet of the dielectric housing and the substrate is preferably less than 35 times the area of the inlet or inlets for process gas. If the dielectric housing has more than one inlet for process gas, as in the apparatus of FIG. 1 which has inlet channels (16) and (17), the surface area of the gap between the outlet of the dielectric housing and the substrate is preferably less than 35 times the sum of the areas of the inlets for process gas.

As an electric potential is applied to the electrodes (11, 12), an electric field is generated around the tips of the electrodes which accelerates charged particles in the gas forming a plasma. The sharp point at the tips of the electrodes aids the process, as the electric field density is inversely proportional to the radius of curvature of the electrode. Needle electrodes (such as 11, 12) possess the benefit of creating a gas breakdown using a lower voltage source because of the enhanced electric field at the sharp extremity of the needles.

Plasma generating apparatus can operate without special provision of a counter electrode. Alternatively a grounded counter electrode may be positioned at any location along the axis of the plasma tube.

The power supply to the electrode or electrodes is a low frequency power supply as known for plasma generation, that is in the range 3 kHz to 300 kHz. Our most preferred range is the very low frequency (VLF) 3 kHz-30 kHz band, although the low frequency (LF) 30 kHz-300 kHz range can also be used successfully. One suitable power supply is the Haiden Laboratories Inc. PHF-2K unit which is a bipolar pulse wave, high frequency and high voltage generator. It has a faster rise and fall time (<3 μs) than conventional sine wave high frequency power supplies. Therefore, it offers better ion generation and greater process efficiency. The frequency of the unit is also variable (1-100 kHz) to match the plasma system. An alternative suitable power supply is an electronic ozone transformer such as that sold under the reference ETI110101 by the company Plasma Technics Inc. It works at fixed frequency and delivers a maximum power of 100 Watt with a working frequency of 20 kHz.

The surface treatment agent which is fed to the atomiser (21) can for example be a polymerisable precursor. When a polymerisable precursor is introduced into the plasma a controlled plasma polymerisation reaction occurs which results in the deposition of a polymer on any substrate which is placed adjacent to the plasma outlet. The precursor can be polymerised to a chemically inert material; for example an organosilicon precursor can be polymerised to a purely inorganic surface coating. Alternatively a range of functional coatings can be deposited onto numerous substrates. These coatings are grafted to the substrate and can retain the functional chemistry of the precursor molecule.

The atomiser (21) preferably uses a gas to atomise the surface treatment agent. For example the process gas used for generating the plasma is used as the atomizing gas to atomise the surface treatment agent. The atomizer (21) can for example be a pneumatic nebuliser, particularly a parallel path nebuliser such as that sold by Burgener Research Inc. of Mississauga, Ontario, Canada, under the trade mark Ari Mist HP, or that described in U.S. Pat. No. 6,634,572. The atomizer can alternatively be an ultrasonic atomizer in which a pump is used to transport the liquid surface treatment agent into an ultrasonic nozzle and subsequently it forms a liquid film onto an atomising surface. Ultrasonic sound waves cause standing waves to be formed in the liquid film, which result in droplets being formed. The atomiser preferably produces drop sizes of from 1 to 100 μm, more preferably from 1 to 50 μm. Suitable atomisers for use in the present invention include ultrasonic nozzles from Sono-Tek Corporation, Milton, N.Y., USA. Alternative atomisers may include for example electrospray techniques, methods of generating a very fine liquid aerosol through electrostatic charging. The most common electrospray apparatus employs a sharply pointed hollow metal tube, with liquid pumped through the tube. A high-voltage power supply is connected to the outlet of the tube. When the power supply is turned on and adjusted for the proper voltage, the liquid being pumped through the tube transforms into a fine continuous mist of droplets. Inkjet technology can also be used to generate liquid droplets without the need of a carrier gas, using thermal, piezoelectric, electrostatic and acoustic methods.

While it is preferred that the atomiser (21) is mounted within the housing (14), an external atomiser can be used. This can for example feed an inlet tube having an outlet in similar position to outlet (23) of nebuliser (21). Alternatively the surface treatment agent, for example in a gaseous state, can be incorporated in the flow of process gas entering chamber (19) either from the channels (17) or through a tube positioned at the location of the nebulizer. In a further alternative the electrode can be combined with the atomizer in such a way that the atomizer acts as the electrode. For example, if a parallel path atomizer is made of conductive material, the entire atomizer device can be used as an electrode. Alternatively a conductive component such as a needle can be incorporated into a non-conductive atomizer to form the combined electrode-atomiser system.

The process gas flow from the inlet past the electrode preferably comprises helium, although another inert gas such as argon or nitrogen can be used. The process gas generally comprises at least 50% by volume helium, and preferably comprises at least 90% by volume, more preferably at least 95%, helium, optionally with up to 5 or 10% of another gas, for example argon, nitrogen or oxygen. A higher proportion of an active gas such as oxygen can be used if it is required to react with the surface treatment agent.

We have found that when using helium as process gas, a plasma jet can stay in laminar flow regime unless steps are taken to change the gas flow regime. When a heavier gas such as argon having a lower kinematic viscosity than helium (kinematic viscosity v is the ratio between the dynamic viscosity and the density of the gas) is used as process gas, the Reynolds number defined as Re=VD/v is larger (V is the fluid velocity and D is the hydraulic diameter of the channel). In the case of argon, the gas flow generally becomes turbulent beyond a centimetre or two into the plasma tube (13). Whilst a laminar flow through the channels (16, 17) to the tips of the electrodes (11, 12) is beneficial in forcing the process gas to pass through the high electric field region, a laminar flow regime has disadvantages when applying a surface treatment agent to a substrate. The directional jets may lead to patterning of the deposition and/or to formation of streamers. A turbulent flow regime gives a more diffuse and more uniform glow like plasma, and measures may be taken to promote a turbulent flow in the plasma tube (13) beyond the tips of the electrodes (11, 12).

One way of promoting turbulent flow in the plasma tube (13) is by controlling the gap (30) between the outlet of the dielectric housing and the substrate. The surface area of the gap (30) between the outlet of the dielectric housing and the substrate is preferably less than 35 times the area of the inlet or inlets for process gas. If the dielectric housing has more than one inlet for process gas, as in the apparatus of FIG. 1 which has inlet channels (16) and (17), the surface area of the gap between the outlet of the dielectric housing and the substrate is preferably less than 35 times the sum of the areas of the inlets for process gas. In the apparatus of FIG. 1 the surface area of the gap (30) is preferably less than 25, more preferably less than 20, times the sum of the areas of the channels (16 and 17). More preferably the surface area of the gap (30) is less than 10 times the area of the inlet or inlets for process gas, for example 2 to 10 times the area of the inlet or inlets for process gas. The gap (30) is preferably 1.5 mm or below, more preferably 1 mm or below, and most preferably 0.75 mm or below, for example 0.25 to 0.75 mm. A turbulent regime can be achieved according to the invention using a larger gap, for example up to 3 mm, with a higher helium flow rate, for example 14 litres/minute, but a smaller gap allows achievement of a turbulent regime at lower helium flow and so more economically viable conditions.

Another method of promoting turbulent flow in the plasma tube (13) is by controlling the velocity of the process gas flowing past the electrode through channels (16,17) to be less than 100 m/s, and also injecting process gas into the dielectric housing at a velocity greater than 100 m/s. The velocity of the helium process gas flowing past the electrodes (11, 12) is preferably at least 3.5 m/s, more preferably at least 5 m/s and may for example be at least 10 m/s. The velocity of this helium process gas flowing past the electrode(s) can for example be up to 70 m/s, preferably up to 50 m/s, particularly up to 30 or 35 m/s. The ratio of process gas flow injected at a velocity greater than 100 m/s to process gas flowing past the electrode at less than 100 m/s is preferably from 1:20 to 5:1. If the atomiser (21) uses helium process gas as the atomizing gas to atomise the surface treatment agent, the atomiser can form the inlet for the process gas injected at a velocity greater than 100 m/s. Alternatively the apparatus may have separate injection tubes for injecting helium process gas at a velocity of above 100 m/s. The outlets of such injection tubes are directed towards the electrodes (11, 12) so that the direction of flow of the high velocity process gas from the injection tubes is counter to the direction of flow of process gas through channels (16, 17) surrounding the electrodes. The velocity of the helium process gas which is injected into the dielectric housing at a velocity greater than 100 m/s can for example be up to 1000 or 1500 m/s and is preferably at least 150 m/s, particularly at least 200 m/s, up to 800 m/s.

The flow rate of the helium process gas flowing through the channels (16, 17) past the electrodes (11, 12) is preferably at least 0.5 l/min and is preferably 10 l/min or below, more preferably 3 l/min or below and most preferably 2 l/min or below. The flow rate of the helium process gas which has a velocity greater than 100 m/s, for example helium used as the atomising gas in a pneumatic nebuliser, is preferably at least 0.5 l/min and can be up to 2 or 2.5 l/min.

The surface treatment agent used in the present invention is a precursor material which is reactive within the non-equilibrium atmospheric pressure plasma or as part of a plasma enhanced chemical vapour deposition (PE-CVD) process and can be used to make any appropriate coating, including, for example, a material which can be used to grow a film or to chemically modify an existing surface. The present invention may be used to form many different types of coatings. The type of coating which is formed on a substrate is determined by the coating-forming material(s) used, and the process of the invention may be used to (co)polymerise coating-forming monomer material(s) onto a substrate surface.

The coating-forming material may be organic or inorganic, solid, liquid or gaseous, or mixtures thereof. Suitable inorganic coating-forming materials include metals and metal oxides, including colloidal metals. Organometallic compounds may also be suitable coating-forming materials, including metal alkoxides such as titanates, tin alkoxides, zirconates, alkoxides of germanium and erbium, alkoxides of aluminium, alkoxides of zinc or alkoxides of indium and/or tin. Particularly preferred silicon-containing precursors for depositing inorganic coatings such as polymerised SiOC films are tetraethyl orthosilicate Si(OC₂H₅)₄ and tetramethylcyclotetrasiloxane (CH₃(H)SiO)₄. Organic compounds of aluminium can be used to deposit alumina coatings on substrates, and a mixture of indium and tin alkoxides can be used to deposit a transparent conductive indium tin oxide coating film.

Tetraethyl orthosilicate is also suitable for depositing SiO₂ layers provided that oxygen is present in the process gas. Deposition of SiO₂ layers can easily be achieved via the addition of O₂ to the processing gas, for example 0.05 to 20% by volume O₂, particularly 0.5 to 10% O₂. Deposition of SiO₂ layers may also be possible without oxygen added in the process gas because of retro-diffusion of oxygen into the plasma tube.

The invention can alternatively be used to provide substrates with siloxane-based coatings using coating-forming compositions comprising silicon-containing materials. Suitable silicon-containing materials for use in the method of the present invention include silanes (for example, silane, alkylsilanes, alkyihalosilanes, alkoxysilanes), silazanes, polysilazanes and linear siloxanes (for example, polydimethylsiloxane or polyhydrogenmethylsiloxane) and cyclic siloxanes (for example, octamethylcyclotetrasiloxane or tetramethylcyclotetrasiloxane), including organo-functional linear and cyclic siloxanes (for example, Si—H containing, halo-functional, and haloalkyl-functional linear and cyclic siloxanes, e.g. tetramethylcyclotetrasiloxane and tri(nonafluorobutyl)trimethylcyclotrisiloxane). A mixture of different silicon-containing materials may be used, for example to tailor the physical properties of the substrate coating for a specified need (e.g. thermal properties, optical properties, such as refractive index, and viscoelastic properties).

Suitable organic coating-forming materials include carboxylates, methacrylates, acrylates, styrenes, methacrylonitriles, alkenes and dienes, for example methyl methacrylate, ethyl methacrylate, propyl methacrylate, butyl methacrylate, and other alkyl methacrylates, and the corresponding acrylates, including organofunctional methacrylates and acrylates, including poly(ethyleneglycol) acrylates and methacrylates, glycidyl methacrylate, trim ethoxysilyl propyl methacrylate, allyl methacrylate, hydroxyethyl methacrylate, hydroxypropyl methacrylate, dialkylaminoalkyl methacrylates, and fluoroalkyl (meth)acrylates, for example heptadecyifluorodecyl acrylate (HDFDA) of the formula

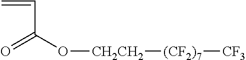

methacrylic acid, acrylic acid, fumaric acid and esters, itaconic acid (and esters), maleic anhydride, styrene, a-methylstyrene, halogenated alkenes, for example, vinyl halides, such as vinyl chlorides and vinyl fluorides, and fluorinated alkenes, for example perfluoroalkenes, acrylonitrile, methacrylonitrile, ethylene, propylene, allyl amine, vinylidene halides, butadienes, acrylamide, such as N-isopropylacrylamide, methacrylamide, epoxy compounds, for example glycidoxypropyltrimethoxysilane, glycidol, styrene oxide, butadiene monoxide, ethyleneglycol diglycidylether, glycidyl methacrylate, bisphenol A diglycidylether (and its oligomers), vinylcyclohexene oxide, conducting polymers such as pyrrole and thiophene and their derivatives, and phosphorus-containing compounds, for example dimethylallylphosphonate. The coating forming material may also comprise acryl-functional organosiloxanes and/or silanes.

The process of the invention is particularly suitable for coating electronic equipment including textile and fabric based electronics printed circuit boards, displays including flexible displays, and electronic components such as semiconductor wafers, resistors, diodes, capacitors, transistors, light emitting diodes (LEDs), organic LEDs, laser diodes, integrated circuits (IC), IC die, IC chips, memory devices logic devices, connectors, keyboards, semiconductor substrates, solar cells, fuel cells. Optical components such as lenses, contact lenses and other optical substrates may similarly be treated. Other applications include military, aerospace or transport equipment, for example gaskets, seals, profiles, hoses, electronic and diagnostic components, household articles including kitchen, bathroom and cookware, office furniture and laboratory ware.

The invention is illustrated by the following Examples

### REFERENCE EXAMPLE 1

The apparatus of FIG. 1 was used to deposit SiOC film on a conductive silicon wafer substrate. The dielectric housing (14) defining the plasma tube (13) was 18 mm in diameter. This housing (14) is made of quartz. The electrodes (11, 12) were each 1 mm diameter and were connected to the Plasma Technics ETI110101 unit operated at 20 kHz and maximum power of 100 watts. Helium process gas was flowed through chamber (19) and thence through channels (16, 17) at 1.5 l/min, corresponding to a velocity of about 5.2 m/s. The channels (16, 17) were each 2 mm in diameter, the electrodes (11, 12) being localized in the centre of each channel. The length of the channels was 14 mm. Each channel has a ratio of length to hydraulic diameter of 14:1. The tip of each needle electrode (11, 12) was positioned within the channel (16, 17 respectively) 2 mm upstream of the exit of the channel.

The atomiser (21) was the Ari Mist HP pneumatic nebuliser supplied by Burgener Inc. Tetramethyltetracyclosiloxane precursor was supplied to the atomiser (21) at 12 μl/min. Helium was fed to the atomiser (21) as atomising gas at 1.2 l/min. The gap (30) between quartz housing (14) and the silicon wafer substrate was 0.75 mm.

For experimental purposes, deposition in static mode was carried out. By static mode we mean that the substrate was not moved relative to the plasma tube outlet. A 12.5×12.5 cm² silicon wafer was used as substrate and the plasma tube positioned at a fixed position at the center of the wafer. Deposition time was controlled to 60 seconds and the weight of deposited film measured using a Sartorius precision scale. The reason for carrying out deposition in static mode is to improve the accuracy of the measurement of the amount of material deposited, although deposition in static mode forms a thicker coating at the center of the wafer than at the outer part of the wafer. A smooth, low porosity SiOC film was deposited on the silicon wafer substrate, having a total weight of 0.00148 g.

### EXAMPLE 1

The procedure of Reference Example 1 was repeated with the tip of each needle electrode (11, 12) being located in the dielectric housing close to the exit of the channel (16, 17 respectively) at a distance 0.5 mm outside the channel exit. A smooth SiOC film was deposited on the silicon wafer substrate. The weight of the film was 0.00195 g. With a channel length to hydraulic diameter ratio of 14:1 we see an improvement in deposition rate when the tip of each needle (11, 12) is outside the channel (16, 17) instead of inside the channel. Even if the flow is not maximally stabilised at this channel length to hydraulic diameter ratio, a benefit in flow stabilisation is visible and sufficient to show improvement in plasma performance when the tip of each needle is moved from inside the channel to outside the channel.

### REFERENCE EXAMPLE 2

Reference Example 1 was repeated using channels (16, 17) each of length 30 mm and the tip located 2 mm inside the channel. Each channel had a ratio of length to hydraulic diameter of 30:1. A smooth, low porosity SiOC film was deposited on the silicon wafer substrate of a weight equal to 0.00168 g.

### EXAMPLE 2

Reference Example 2 was repeated with the tip of each needle electrode (11, 12) being located in the dielectric housing at a distance 0.5mm outside the exit of the channel (16, 17 respectively) instead of being inside the channel. A smooth SiOC film was deposited on the silicon wafer substrate. The weight of the film deposited was 0.00277 g. We observe that when the tips of the needles (11, 12) are a short distance outside the channels (16, 17), the weight of the SiOC film deposited increases significantly from 0.00195 g to 0.00277 g when increasing the channel length to hydraulic diameter ratio from 14:1 to 30:1. At the channel length to hydraulic diameter ratio of 30:1 we have complete flow stabilisation, and positioning the tips of the needles (11, 12) a short distance outside the channels (16, 17) takes maximum benefit from the stabilised flow in plasma generation.

### REFERENCE EXAMPLE 3

The apparatus of FIG. 1 was used to deposit SiOC film on a conductive silicon wafer substrate. The dielectric housing (14) defining the plasma tube (13) was 18 mm in diameter. This housing (14) is made of quartz. The electrodes (11, 12) were each 1 mm diameter and were connected to the Plasma Technics ETI110101 unit operated at 20 kHz and maximum power of 100 watts. Helium process gas was flowed through chamber (19) and thence through channels (16, 17) at 1 l/min, corresponding to a velocity of about 3.5 m/s. The channels (16, 17) were each 2 mm in diameter, the electrodes (11, 12) being localized in the centre of each channel. The length of the channels was 14 mm. Each channel has a ratio of length to hydraulic diameter of 14:1. The tip of each needle electrode (11, 12) was positioned within the channel (16, 17 respectively) 2 mm upstream of the exit of the channel.

The atomiser (21) was the Ari Mist HP pneumatic nebuliser supplied by Burgener Inc. Tetramethyltetracyclosiloxane precursor was supplied to the atomiser (21) at 12 μl/min. Helium was fed to the atomiser (21) as atomising gas at 1.2 l/min. The gap (30) between quartz housing (14) and the silicon wafer substrate (25) was 0.75 mm.

Deposition in dynamic mode was carried out. By dynamic mode we mean that the plasma tube (13) was moved relative to the substrate (25) so that different areas of the substrate are exposed to the plasma for approximately the same time to achieve a coating film of substantially uniform thickness, as normally required in commercial practice. Deposition time was controlled to 180 s. A smooth SiOC film was deposited on the silicon wafer substrate. The thickness of the film deposited was 1700 Angstrom units.

### EXAMPLE 3

Reference Example 3 was repeated using channels (16,17) each of length 30 mm and with the tip of each needle electrode being 0.5 mm downstream of the end of the corresponding channel. Each channel had a ratio of length to hydraulic diameter of 30:1. A smooth, low porosity SiOC film was deposited on the silicon wafer substrate, but the thickness of the film was 4100 Angstrom units.

When Example 3 and Reference Example 3 were repeated using higher helium process gas flows of 2 and 3 l/min, there was a lower difference between the Example and the Reference Example. The benefits of having the tip of the needle electrode positioned close to the exit of the channel at a distance outside the channel of at least 0.5 mm up to 5 times the hydraulic diameter of the channel and of channels having a high ratio of length to effective diameter are seen particularly at low helium gas flows, which are the conditions that are the more economically viable.

1. An apparatus for plasma treating a substrate, comprising a high voltage source connected to at least one needle electrode (11) positioned within a channel (16) inside a dielectric housing (14) having an inlet for process gas and an outlet, the channel having an entry (16a) which forms the said inlet for process gas and an exit (16e) into the dielectric housing (14) arranged so that process gas flows from the inlet through the channel (16) past the electrode (11) to the outlet of the dielectric housing (14), means for introducing an atomised surface treatment agent in the dielectric housing (14), and support means (27, 28) for a substrate (25) adjacent to the outlet of the dielectric housing (14), wherein the needle electrode (11) extends from the channel entry (16a) to a tip (11t) close to the exit (16e) of the channel (16) and projects outwardly from the channel (16) so that the tip (11t) of the needle electrode (11) is positioned in the dielectric housing close to the exit (16e) of the channel (16) at a distance outside the channel (16) of at least 0.5 mm up to 5 times the hydraulic diameter of the channel, and the channel (16) has a ratio of length to hydraulic diameter of at least 10:1.

2. An apparatus according to claim 1, wherein the channel (16) has a ratio of length to hydraulic diameter of at least 20:1.

3. An apparatus according to claim 2, wherein the channel (16) has a ratio of length to hydraulic diameter of at least 30:1.

4. An apparatus according to claim 1 wherein the high voltage source has a frequency of 3 kHz to 300 kHz.

5. An apparatus according to claim 1 wherein the means for introducing a surface treatment agent comprises an atomiser (21) wherein a gas is used to atomise the surface treatment agent, the atomiser being positioned within the dielectric housing (14).

6. An apparatus according to claim 5, wherein the high voltage source is connected to at least two needle electrodes (11, 12) positioned within the dielectric housing (14) surrounding the atomiser (21) and having the same polarity, each electrode (11, 12) being a needle electrode surrounded by the channel (16), with the tip of each needle electrode being positioned close to the exit of the associated channel.

7. A process for plasma treating a substrate by applying a high voltage to at least one needle electrode (11) positioned within a channel (16) inside a dielectric housing (14) having an inlet for process gas and an outlet, the channel having an entry (16a) which forms the inlet for process gas and an exit (16e) into the dielectric housing (14), while causing a process gas to flow from the inlet through the channel (16) past the electrode (11) to the outlet of the dielectric housing (14), thereby generating a non-local thermal equilibrium atmospheric pressure plasma, incorporating an atomised or gaseous surface treatment agent in the non-local thermal equilibrium atmospheric pressure plasma, and positioning a substrate (25) adjacent to the outlet of the dielectric housing (14) so that the surface of the substrate (25) is in contact with the plasma and is moved relative to the outlet of the dielectric housing (14), wherein the needle electrode (11) extends from the channel entry (16a) to a tip (11t) close to the exit (16e) of the channel (16) and projects outwardly from the channel (16) so that the tip (11t) of the needle electrode (11) is positioned in the dielectric housing (14) close to the exit (16e) of the channel (16) at a distance outside the channel (16) of at least 0.5 mm up to 5 times the hydraulic diameter of the channel, and the channel (16) has a ratio of length to hydraulic diameter of at least 10:1.

8. A process according to claim 7 wherein the process gas is helium.

9. A process according to claim 7 wherein the velocity of the process gas flowing through the channel (16) past the needle electrode (11) is less than 100 m/s.

10. A process according to claim 9 wherein process gas is also injected into the dielectric housing at a velocity greater than 100 m/s, the volume ratio of process gas injected at a velocity greater than 100 m/s to process gas flowing past the electrode (11) at less than 100 m/s being from 1:20 to 5:1.

11. A process according to claim 7, wherein the surface area of the gap (30) between the outlet (15) of the dielectric housing (14) and the substrate (25) is less than 35 times the sum of the areas of the inlets for process gas.

12. An apparatus according to claim 2 wherein the high voltage source has a frequency of 3 kHz to 300 kHz.

13. An apparatus according to claim 3 wherein the high voltage source has a frequency of 3 kHz to 300 kHz.

14. A process according to claim 8 wherein the velocity of the process gas flowing through the channel (16) past the needle electrode (11) is less than 100 m/s
